(19) United States
(12) Patent Application Publication
(10) Pub. No.: US 2024/0084137 A1
(43) Pub. Date: Mar. 14, 2024

(54) RESIN COMPOSITION, RESIN ADHESIVE FILM, AND APPLICATION THEREOF

(71) Applicant: SHENGYI TECHNOLOGY CO., LTD., Dongguan, Guangdong Province (CN)

(72) Inventors: Dongliang LIU, Dongguan (CN); Qing WANG, Dongguan (CN); Junqi TANG, Dongguan (CN); Jinchao DONG, Dongguan (CN)

(21) Appl. No.: 18/266,040

(22) PCT Filed: Mar. 19, 2021
(86) PCT No.: PCT/CN2021/081801

§ 371 Date: Jun. 8, 2023

(30) Foreign Application Priority Data
Dec. 30, 2020 (CN) 202011607146.4

(51) Int. Cl. C08L 81/06; C08K 9/06; C08L 79/08

(52) U.S. Cl. CPC C08L 81/06; C08K 9/06; C08L 79/08; C08K 5/29

(57) ABSTRACT

Resin composition, resin adhesive film, and application thereof. The resin composition comprises the following components in parts by weight: 80-120 parts an epoxy resin, 1-20 parts a carbodiimide compound, 30-130 parts a phenolic resin, 20-250 parts a modified polymer, and 50-500 parts silicon dioxide; where the modified polymer is selected from a polyethersulfone or a polyamide-imide resin. By means of selection and compounding of components, the present resin composition has a uniquely advantageous film forming property, effectively solves the problem of a semi-cured resin adhesive film being prone to cracking or fracture, has outstanding heat resistance, a high glass transition temperature, a high modulus, good strength and toughness, and can to form a high strength stable bond with a metal film, has uniquely advantageous reliability, can amply satisfy printed circuit board and chip packaging performance requirements, and is suitable in a variety of chip packaging processes.

### CROSS REFERENCE TO RELATED APPLICATIONS

This patent application is a national phase under 35 U.S.C. § 371 of International Patent Application No. PCT/CN2021/081801 filed Mar. 19, 2021, which claims the benefit of priority from Chinese Patent Application No. 202011607146.4 filed Dec. 30, 2020, each of which is hereby incorporated herein by reference in its entirety for all purposes.

### TECHNICAL FIELD

The present application belongs to the technical field of printed circuit boards, and particularly relates to a resin composition, a resin adhesive film and an application thereof.

### BACKGROUND

The IC package substrate, also known as IC carrier board, is the bridge for connecting IC and the printed circuit board (PCB), which is the essential core electronic material. The material of IC carrier board can be divided into two types: BT (Bismaleimide Triazine) resin-based copper-clad laminate, abbreviated as BT board; ABF (Ajinomoto Buildup Film). The BT material has a glass fiber yarn layer and is harder than the FC substrate of the ABF material, the wiring is troublesome, and the difficulty of laser drilling is high, which cannot satisfy the requirements of fine lines; however, the BT material can stabilize the size and prevent heat expansion and cold contraction from affecting the line yield; therefore, the BT material is mostly used for network chips and programmable logic chips with high reliability requirements, which relatively belongs to a niche market. The ABF material is led by Intel and can be used as IC with the thinner circuit, high pin count and high transmission, which relatively aims at the mass market to be applied to graphics chips, processors, chipset, etc. ABF is a build-up material, and fine line circuits with line width less than 30 μm or even less than 10 μm can be formed on the ABF surface by additive process of directly attaching ABF to the copper foil substrate. In addition, the ABF packaging substrate is also widely used in larger size chips CPU, GPU, FPGA, network processors, and other aspects.

With the development of electronic products for multi-function, light weight and miniaturization, the semiconductor manufacturing process continues to advance. Processors applied to electronic equipment such as smart phones and tablet computers have begun to extensively use processes of 28 nm or 14 nm. In addition, the demand for high performance computing (HPC) for artificial intelligence and self-driving cars has increased dramatically, and the technologies of 10/7 nm HPC computing chips and application-specific integrated circuit (ASIC) used in the new generation have been continuously developed. The flip chip chip scale package (FCCSP) substrate of ABF material can meet the requirements of fine lines, small line width and small line space, and has the characteristics of stable size, fast signal transmission, high thermal conductivity, high reliability, etc., so it has been adopted by more IC designers. From the perspective of the development trend of the industry, BT-FCCSP substrate will encounter a bottleneck in the miniaturization due to the physical characteristics, while the ABF-FCCSP substrate can satisfy the advanced semiconductor manufacturing process, showing a good development potential.

The ABF film is an important raw material for preparing the ABF-FCCSP substrate, but the research on the ABF film material is not pervasive and in-depth at present, and the existing ABF film cannot meet the comprehensive requirements of high heat resistance, high adhesive strength, high mechanical strength, good film-forming performance and the like. For example, CN107722623A discloses a resin composition including an elastomer having a polycarbonate structure in the molecule, an epoxy resin, an inorganic filler, a phenoxy resin, and a carbodiimide compound; the resin composition has good strength and adhesive performance and low warpage, but has poor heat resistance, and is prone to delamination and blistering after thermal shock or reflow soldering treatment, which thus is difficult to meet the processing requirements of electronic components. TW201704333A discloses a resin composition including an epoxy resin, a curing agent, a curing accelerator, a carbodiimide compound and a filler, in which the curing agent includes a phenolic resin; the resin composition has good thermal conductivity and adhesive force with a metal layer, but has a poor film-forming performance, and is prone to resin cracking or fracture when prepared into the resin film, and especially, the resin composition is difficult to prepare the resin film having a large thickness.

Therefore, it has been an urgent problem to be solved in the art to develop a resin material having excellent film-forming performance, heat resistance, mechanical strength, adhesive performance, and stability to meet the requirements of high performance printed circuit boards and chip packaging technology.

### SUMMARY

In view of the defects in the prior art, the present application is to provide a resin composition, a resin adhesive film and an application thereof. By selecting and combining the specific polymer components, the resin composition is enabled to have excellent heat resistance, film-forming performance, high modulus, good strength and toughness, high adhesive force with the metal layer, no powder falling, and good reliability, which is applicable for a variety of chip packaging processes and has promising application prospect.

To achieve the object, the present application adopts the technical solutions below.

In a first aspect, the present application provides a resin composition, and the resin composition includes the following components in parts by weight: 80-120 parts of an epoxy resin, 1-10 parts of a carbodiimide compound, 30-130 parts of a phenolic resin, 20-250 parts of a modified polymer and 50-500 parts of silicon dioxide; the modified polymer is selected from polyethersulfone or a polyamide-imide resin.

The resin composition provided by the present application includes a combination of specific parts by weight of epoxy resin, carbodiimide compound, phenolic resin, modified polymer and silicon dioxide, in which the modified polymer is polyethersulfone or a polyamide-imide resin. On one hand, the modified polymer performs a synergetic effect with the carbodiimide compound and the phenolic resin to react with the epoxy resin together, so that a more dense and more stable three-dimensional crosslink network is formed in the cured product, increasing the glass transition temperature and heat resistance of the resin composition, and meanwhile, secondary hydroxyl is generated which regulates the cohesive strength and the adhesive performance of the resin composition and improves the adhesive force between the resin composition and the metal foil; on the other hand, the modified polymer is combined with silicon dioxide to reinforce and toughen the resin composition, giving the resin composition high modulus, high strength and high toughness. By selecting and combining the components, the resin composition of the present application has excellent film-forming performance, which effectively solves the problem that the semi-cured resin adhesive film is easy to crack or fracture, and has outstanding heat resistance, high glass transition temperature, high modulus, good strength and toughness, high adhesive force with metal foil, and excellent reliability, which fully satisfies the performance requirements of printed circuit boards and chip packaging and is applicable for a variety of chip packaging processes (for example, an SAP process, an RDL process or an SLP process and the like).

In the resin composition provided by the present application, the epoxy resin is 80-120 parts, for example, 82 parts, 85 parts, 88 parts, 90 parts, 92 parts, 95 parts, 98 parts, 100 parts, 102 parts, 105 parts, 108 parts, 110 parts, 112 parts, 115 parts or 118 parts, or any specific point values between the above point values, and the specific point values included in the range will not be exhaustively listed in the present application for the sake of space and brevity.

The carbodiimide compound is 1-10 parts, for example, 1.5 parts, 2 parts, 2.5 parts, 3 parts, 3.5 parts, 4 parts, 4.5 parts, 5 parts, 5.5 parts, 6 parts, 6.5 parts, 7 parts, 7.5 parts, 8 parts, 8.5 parts, 9 parts or 9.5 parts, or any specific point values between the above point values, and the specific point values included in the range will not be exhaustively listed in the present application for the sake of space and brevity.

The phenolic resin is 30-130 parts, for example, 35 parts, 40 parts, 45 parts, 50 parts, 55 parts, 60 parts, 65 parts, 70 parts, 75 parts, 80 parts, 85 parts, 90 parts, 95 parts, 100 parts, 105 parts, 110 parts, 115 parts, 120 parts or 125 parts, or any specific point values between the above point values, and the specific point values included in the range will not be exhaustively listed in the present application for the sake of space and brevity.

The modified polymer is 20-250 parts, for example, 30 parts, 40 parts, 50 parts, 60 parts, 70 parts, 80 parts, 90 parts, 100 parts, 110 parts, 120 parts, 130 parts, 140 parts, 150 parts, 160 parts, 170 parts, 180 parts, 190 parts, 200 parts, 210 parts, 220 parts, 230 parts or 240 parts, or any specific point values between the above point values, and the specific point values included in the range will not be exhaustively listed in the present application for the sake of space and brevity.

The silicon dioxide is 50-500 parts, for example, 60 parts, 70 parts, 80 parts, 90 parts, 100 parts, 110 parts, 130 parts, 150 parts, 170 parts, 190 parts, 200 parts, 210 parts, 230 parts, 250 parts, 270 parts, 290 parts, 300 parts, 310 parts, 330 parts, 350 parts, 370 parts, 390 parts, 400 parts, 410 parts, 430 parts, 450 parts, 470 parts or 490 parts, or any specific point values between the above point values, and the specific point values included in the range will not be exhaustively listed in the present application for the sake of space and brevity.

Preferably, the epoxy resin includes any one or a combination of at least two of a bisphenol A epoxy resin, a bisphenol F epoxy resin, a biphenyl epoxy resin, an epoxy resin having a naphthalene structure, a dicyclopentadiene (DCPD) epoxy resin or a PPO (polyphenylene ether) modified epoxy resin.

Preferably, the epoxy resin is a liquid epoxy resin and/or a solid epoxy resin.

Preferably, the carbodiimide compound has a weight average molecular mass of 500-5000, for example, 600, 700, 800, 900, 1000, 1100, 1300, 1500, 1700, 1900, 2000, 2100, 2300, 2500, 2700, 2900, 3000, 3100, 3300, 3500, 3700, 3900, 4000, 4100, 4300, 4500, 4700 or 4900, or any specific point values between the above point values, and the specific point values included in the range will not be exhaustively listed in the present application for the sake of space and brevity. The weight average molecular of the present application is obtained by the method specified in GB/T 21863-2008, and is determined by gel permeation chromatography (GPC) based on polystyrene calibration.

Preferably, the carbodiimide compound and the epoxy resin have a mass ratio of (0.01-0.1):1, for example, 0.015:1, 0.02:1, 0.025:1, 0.03:1, 0.035:1, 0.04:1, 0.045:1, 0.05:1, 0.055:1, 0.06:1, 0.065:1, 0.07:1, 0.075:1, 0.08:1, 0.085:1, 0.09:1 or 0.095:1.

As a preferred technical solution of the present application, the carbodiimide compound is combined with the epoxy resin in a specific mass ratio, which enables the resin composition to have more appropriate cohesive strength and better adhesion performance and improves the adhesive force between the resin composition and the metal foil. If the amount of the carbodiimide compound is too low, the adhesive force of the resin composition will decrease; if the carbodiimide compound is added in an excessive amount, the heat resistance and dielectric performance of the resin will be affected.

Preferably, the phenolic resin includes any one or a combination of at least two of a biphenyl phenolic resin, an o-cresol phenolic resin, a phenolic resin having a naphthalene structure or a dicyclopentadiene phenolic resin.

Preferably, the phenolic resin and the epoxy resin have a reactive-group equivalent ratio of (0.80-0.95):1, for example, 0.81:1, 0.82:1, 0.83:1, 0.84:1, 0.85:1, 0.86:1, 0.87:1, 0.88:1, 0.89:1, 0.90:1, 0.91:1, 0.92:1, 0.93:1 or 0.94:1.

As a preferred technical solution of the present application, the phenolic resin (hydroxyl) and the epoxy resin (epoxy group) have a reactive-group equivalent ratio of (0.80-0.95):1, which enables the resin composition to have high crosslinking density and excellent heat resistance and toughness. If the amount of the phenolic resin is too low, the crosslinking degree of the resin composition will decrease, affecting the glass transition temperature and heat resistance; if the amount of the phenolic resin is too high, the resin composition will be brittle and the toughness will decrease.

Preferably, based on a total mass of the epoxy resin, the carbodiimide compound and the phenolic resin being 100%, a mass of the modified polymer is 30-100%, for example, 32%, 35%, 38%, 40%, 42%, 45%, 48%, 50%, 52%, 55%, 58%, 60%, 62%, 65%, 68%, 70%, 72%, 75%, 78%, 80%, 82%, 85%, 88%, 90%, 92%, 95% or 98%, or any specific point values between the above point values, and the specific point values included in the range will not be exhaustively listed in the present application for the sake of space and brevity.

As a preferred technical solution of the present application, a mass of the modified polymer is 30-100% of a total mass of the epoxy resin, the carbodiimide compound and the phenolic resin, which enables the resin composition to have both high glass transition temperature and high modulus and to have excellent film-forming performance, heat resistance, toughness, and adhesive performance. If the amount of the modified polymer is too much, the compatibility of the resin composition will be poor, affecting the uniformity of the resin adhesive film and the printed circuit board, and appearance defects appear; if the amount of the modified polymer is too low, the heat resistance and modulus of the resin composition are low, which cannot meet the use requirements.

Preferably, the polyethersulfone has a weight average molecular mass of 5000-50000, for example, 6000, 8000, 10000, 12000, 15000, 18000, 20000, 22000, 25000, 28000, 30000, 32000, 35000, 38000, 40000, 42000, 45000 or 48000, or any specific point values between the above point values, and the specific point values included in the range will not be exhaustively listed in the present application for the sake of space and brevity.

Preferably, the polyethersulfone has a structure as shown by Formula I:

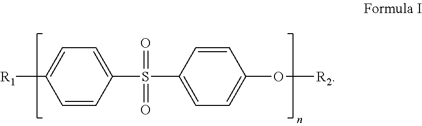

In Formula I, R1 and R2 are each independently selected from carboxyl, hydroxyl, amino or C6-C18 (for example, C6, C9, C10, C12, C14, C16 or C18) aryl with a substituent; the substituent is selected from at least one of carboxyl, hydroxyl or amino.

In Formula I, n represents an average value of a repeating unit, 10≤n≤250, and for example, n may be 15, 20, 25, 30, 35, 40, 45, 50, 55, 60, 70, 80, 90, 100, 110, 130, 150, 170, 190, 200, 210, 220, 230, 240 or 245, or any specific point values between the above point values, and the specific point values included in the range will not be exhaustively listed in the present application for the sake of space and brevity.

Preferably, the polyethersulfone includes a polyethersulfone having hydroxyl.

Preferably, the polyethersulfone having hydroxyl has a hydroxyl content of 10-500 μeq/g, for example, 20 μeq/g, 30 μeq/g, 50 μeq/g, 70 μeq/g, 90 μeq/g, 100 μeq/g, 120 μeq/g, 150 μeq/g, 180 μeq/g, 200 μeq/g, 220 μeq/g, 250 μeq/g, 280 μeq/g, 300 μeq/g, 320 μeq/g, 350 μeq/g, 380 μeq/g, 400 μeq/g, 420 μeq/g, 450 μeq/g or 480 μeq/g, or any specific point values between the above point values, and the specific point values included in the range will not be exhaustively listed in the present application for the sake of space and brevity.

Preferably, the polyamide-imide resin has a weight average molecular mass of 5000-50000, for example, 6000, 8000, 10000, 12000, 15000, 18000, 20000, 22000, 25000, 28000, 30000, 32000, 35000, 38000, 40000, 42000, 45000 or 48000, or any specific point values between the above point values, and the specific point values included in the range will not be exhaustively listed in the present application for the sake of space and brevity.

Preferably, the polyamide-imide resin has a repeating unit having a structure as shown in Formula II:

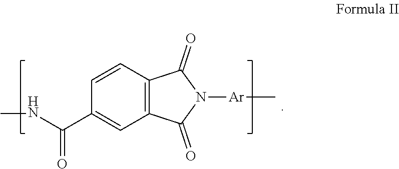

In Formula II, Ar is selected from C6-C18 arylene, for example, C6, C9, C10, C12, C14, C16 or C18 aryl, which illustratively includes but not limited to phenylene, biphenylene, naphthylene, anthracene, phenanthrene, fluorenylidene or indenylidene.

As a preferred technical solution of the present application, the modified polymer (polyethersulfone or a polyamide-imide resin) independently has a weight average molecular mass of 5000-50000. If the weight average molecular mass of the modified polymer is too high, the solubility of the modified polymer will be poor, affecting the processability and fluidity of the resin composition; if the molecular mass of the modified polymer is too low, the toughening effect will be weakened, resulting in a decrease in the modulus, toughness, and heat resistance of the resin composition.

Preferably, the silicon dioxide has a mass percentage of 40-80% in the resin composition, for example, 42%, 45%, 48%, 50%, 52%, 55%, 58%, 60%, 62%, 65%, 68%, 70%, 72%, 75% or 78%, or any specific point values between the above point values, and the specific point values included in the range will not be exhaustively listed in the present application for the sake of space and brevity.

Preferably, the silicon dioxide is spherical silicon dioxide.

Preferably, the spherical silicon dioxide has a particle size of less than or equal to 2 μm, for example, 1.9 μm, 1.7 μm, 1.5 μm, 1.3 μm, 1.1 μm, 1 μm, 0.9 μm, 0.7 μm, 0.5 μm, 0.3 μm, 0.1 μm, 0.08 μm, 0.05 μm, 0.03 μm or 0.01 μm; if the particle size of the spherical silicon dioxide is too large, the line width and accuracy of the printed circuit board will be affected. The particle size of the present application is measured by a Malvern laser particle size analyzer.

Preferably, the spherical silicon dioxide includes nano-sized silicon dioxide, and the nano-sized silicon dioxide has a particle size of 10-100 nm, for example, 15 nm, 20 nm, 25 nm, 30 nm, 35 nm, 40 nm, 45 nm, 50 nm, 55 nm, 60 nm, 65 nm, 70 nm, 75 nm, 80 nm, 85 nm, 90 nm or 95 nm, or any specific point values between the above point values, and the specific point values included in the range will not be exhaustively listed in the present application for the sake of space and brevity.

Preferably, based on a total mass of the organic compounds in the resin composition being 100%, the nano-sized silicon dioxide has a mass of 1-10%, for example, 1.5%, 2%, 2.5%, 3%, 3.5%, 4%, 4.5%, 5%, 5.5%, 6%, 6.5%, 7%, 7.5%, 8%, 8.5%, 9% or 9.5%, or any specific point values between the above point values, and the specific point values included in the range will not be exhaustively listed in the present application for the sake of space and brevity.

As a preferred technical solution of the present application, the silicon dioxide is spherical silicon dioxide including a combination of micron-sized silicon dioxide and nano-sized silicon dioxide; the nano-sized silicon dioxide and the modified polymer perform a synergistic effect and improve the modulus, strength and toughness of the resin composition; however, if the amount of the nano-sized silicon dioxide is too large (more than 10% of the mass of the organic compounds), the nano-sized silicon dioxide will have poor dispersibility in the resin system and will be prone to agglomeration, resulting in performance deterioration of the resin composition.

Preferably, the silicon dioxide is silicon dioxide with surface treatment.

Preferably, an agent used for the surface treatment is a coupling agent, and more preferably a silane coupling agent.

Preferably, the resin composition further includes 0.01-5 parts of a curing accelerator by weight, for example, the curing accelerator may be 0.03 parts, 0.05 parts, 0.08 parts, 0.1 parts, 0.3 parts, 0.5 parts, 0.8 parts, 1 part, 1.5 parts, 2 parts, 2.5 parts, 3 parts, 3.5 parts, 4 parts, 4.5 parts or 4.8 parts, or any specific point values between the above point values, and the specific point values included in the range will not be exhaustively listed in the present application for the sake of space and brevity.

Preferably, the curing accelerator and the epoxy resin have a mass ratio of (0.0005-0.01):1, for example, 0.0008:1, 0.001:1, 0.002:1, 0.003:1, 0.004:1, 0.005:1, 0.006:1, 0.007:1, 0.008:1, 0.009:1 or 0.0095:1.

Preferably, the curing accelerator includes any one or a combination of at least two of an imidazole compound, an organic phosphorus, an organic amine, a quaternary ammonium salt, a peroxide or an organometallic salt, and more preferably an imidazole compound.

Preferably, the imidazole curing accelerator includes any one or a combination of at least two of imidazole, 2-methylimidazole, 2-methyl-4-ethylimidazole, 2-phenylimidazole or 2-undecyl imidazole.

Preferably, the organic phosphorus includes any one or a combination of at least two of tributylphosphine, triphenylphosphine or tripropylphosphine.

Preferably, the organic amine includes a tertiary amine compound, and more preferably benzyldimethylamine.

Preferably, the peroxide includes any one or a combination of at least two of dicumyl peroxide, 2,5-dimethyl-2,5-di(tert-butylperoxy)hexyne-3,2,5-dimethyl-2,5-di(tert-butylperoxy)hexane or α,α′-bis(tert-butylperoxy)dicumyl.

Preferably, the organometallic salt includes any one or a combination of at least two of zinc naphthenate, cobalt naphthenate, tin octoate or cobalt octoate.

In a second aspect, the present application provides a resin varnish, and the resin varnish includes a solvent, and the resin composition according to the first aspect dissolved or dispersed in the solvent.

In the present application, the type of solvent is not particularly limited, and the solvent includes any one or a combination of at least two of an alcohol solvent, an ether solvent, a ketone solvent, an aromatic hydrocarbon solvent, an ester solvent or a nitrogen-containing solvent.

The solid content of the resin varnish is not particularly limited and can be adaptively adjusted according to actual processing requirements.

In a third aspect, the present application provides a resin adhesive film, and a material of the resin adhesive film includes the resin composition according to the first aspect.

Preferably, the resin adhesive film includes a carrier and a resin layer arranged on the carrier; a material of the resin layer includes the resin composition according to the first aspect.

Preferably, the carrier includes a polymer film, and more preferably any one of a polyethylene terephthalate (PET) film, a polybutylene terephthalate (PBT) film or a polyethylene naphthalate (PEN) film.

Preferably, the resin layer is further provided with a protective film.

Preferably, the protective film is a release material, and more preferably a polyethylene (PE) film or a polypropylene (PP) film; the polypropylene film can be a biaxially oriented polypropylene (BOPP) film.

As a preferred technical solution of the present application, the resin adhesive film includes a carrier, a resin layer and a protective film arranged in sequence; the material of the resin layer is the resin composition according to the first aspect; the carrier is preferably a PET film and the protective film is preferably a PE film or a BOPP film.

Exemplarily, the resin adhesive film is prepared by the following method including: coating a varnish of the resin composition on a carrier and drying; then attaching a protective film onto the resin layer and pressing to obtain the resin adhesive film.

Preferably, the drying is performed at 80-160° C., for example, 85° C., 90° C., 95° C., 100° C., 105° C., 110° C., 115° C., 120° C., 125° C., 130° C., 135° C., 140° C., 145° C., 150° C. or 155° C.

Preferably, the drying is performed for 1-10 min, for example, 2 min, 3 min, 4 min, 5 min, 6 min, 7 min, 8 min or 9 min.

Preferably, the pressing is performed in a manner of roller pressing.

Preferably, the pressing is performed at 80-120° C., for example, 82° C., 85° C., 88° C., 90° C., 92° C., 95° C., 98° C., 100° C., 102° C., 105° C., 108° C., 110° C., 120° C., 115° C. or 118° C.

Preferably, the pressing is performed at 0.1-3 MPa, for example, 0.2 MPa, 0.5 MPa, 0.8 MPa, 1 MPa, 1.2 MPa, 1.5 MPa, 1.8 MPa, 2 MPa, 2.2 MPa, 2.5 MPa or 2.8 MPa.

In a fourth aspect, the present application provides an application of the resin adhesive film according to the third aspect in a printed circuit board or chip packaging.

Compared with the prior art, the present application has the beneficial effects below.
(1) The resin composition provided by the present application includes the combination of an epoxy resin, a carbodiimide compound, a phenolic resin, a modified polymer and silicon dioxide; by selecting and combining the components, the problem is effectively solved that the semi-cured resin adhesive film is easy to crack or fracture; accordingly, the resin composition has excellent film-forming performance and heat resistance, high glass transition temperature, high modulus, good strength and toughness, and high adhesive force with metal foil, which fully satisfies the performance requirements of printed circuit boards and chip packaging.
(2) By further optimizing the components and their respective amounts in the resin composition, the resin adhesive film and printed circuit board containing the resin composition have high glass transition temperature (Tg≥173° C.), the moisture and heat resistance stability test (with immersion tin at 288° C.) is performed for more than 30 min, the reflow soldering is performed for more than times, the peel strength is 0.80-0.85 N/mm, the modulus is 6.0-6.6 GPa, and the resin products of the present application do not shed powders or crack and have excellent film-forming performance, heat resistance, moisture and heat resistance, resin fluidity, peel strength and reliability, which are applicable for a variety of chip packaging processes.

### DETAILED DESCRIPTION

The technical solutions of the present application are further described below through embodiments. It should be apparent to those skilled in the art that the embodiments are merely used for a better understanding of the present application but should not be construed as a limitation on the present application.

### Example 1

A resin composition includes the following components in parts by weight: 100 parts of an epoxy resin (ZX1059 of Nippon Steel & Sumikin Chemical Co., Ltd, HP-4710 of DIC, and NC3000 of Nippon Kayaku Co., Ltd combined at a mass ratio of 10:40:50), 5 parts of a carbodiimide compound (CARBODIIMIDE V-07 of Nisshinbo Chemical Inc), 50 parts of polyethersulfone (3000RP of SOLVAY), 45 parts of a phenolic resin (SN375 of Nippon Steel Chemical), 200 parts of silicon dioxide and 0.1 part of a curing accelerator (2-methylimidazole, 2-MI); the silicon dioxide includes 198 parts of micron-sized silicon dioxide (with an average particle size of 1 μm) and 2 parts of nano-sized silicon dioxide (with an average particle size of 50 nm).

A resin adhesive film includes a carrier (PET film), a resin layer (with a thickness of 40 μm) and a protective film (BOPP film) arranged in sequence, and a material of the resin layer is the resin composition provided by this example; a preparation method is as follows:
(1) the resin composition was mixed with a solvent (butanone) and uniformly dispersed to obtain a resin varnish with a solid content of 60%; and
(2) the resin varnish obtained in step (1) was coated on one surface of a PET film and then placed into an oven and baked at 120° C. for 4 min to remove the solvent, and the resin layer was attached with a BOPP film and roller-pressed at 100° C. and 1.5 MPa to obtain the resin adhesive film.

A printed circuit board (PCB) is provided, which is prepared by the following method: the BOPP film of the resin adhesive film provided by this example was removed away, the resin layer was arranged into contact with a carrier board and pressed at 100° C. and 10 kgf/cm² for 2 min, the PET film was removed away, and the resin layer and carrier board were placed into an oven at 190° C., cured for 60 min, cooled, then taken out, and then manufactured into a PCB with fine circuit lines by the semi-additive process (SAP), i.e., using laser drilling, DESMEAR process, chemical deposition of copper and electroplating.

### Example 2

A resin composition includes the following components in parts by weight: 100 parts of an epoxy resin (ESN-375 of Nippon Steel & Sumikin Chemical Co., Ltd and NC3000 of Nippon Kayaku Co., Ltd combined at a mass ratio of 50:50), 5 parts of a carbodiimide compound (Stabaxol P2400 of Rhein Chemie), 205 parts of polyethersulfone (3000RP of SOLVAY), 100 parts of a phenolic resin (SH-5085 of Shandong Shengquan Co., Ltd), 400 parts of silicon dioxide and 0.1 part of a curing accelerator (2-MI); the silicon dioxide includes 380 parts of micron-sized silicon dioxide (with an average particle size of 1.1 μm) and 20 parts of nano-sized silicon dioxide (with an average particle size of 50 nm).

A resin adhesive film is provided, which differs from Example 1 only in that a material of the resin layer is the resin composition provided by this example; other materials and preparation method are the same as in Example 1.

A PCB is provided, which differs from Example 1 only in that a resin adhesive film is the resin adhesive film provided by this example; other materials and preparation method are the same as in Example 1.

### Example 3

A resin composition includes the following components in parts by weight: 100 parts of an epoxy resin (ESN-375 of Nippon Steel & Sumikin Chemical Co., Ltd and NC3000 of Nippon Kayaku Co., Ltd combined at a mass ratio of 50:50), 5 parts of a carbodiimide compound (Stabaxol P2400 of Rhein Chemie), 50 parts of polyethersulfone (3000RP of SOLVAY), 45 parts of a phenolic resin (SH-5085 of Shandong Shengquan Co., Ltd), 200 parts of silicon dioxide and 0.1 part of a curing accelerator (2-MI); the silicon dioxide includes 180 parts of micron-sized silicon dioxide (with an average particle size of 1.5 μm) and 20 parts of nano-sized silicon dioxide (with an average particle size of 50 nm).

A resin adhesive film is provided, which differs from Example 1 only in that a material of the resin layer is the resin composition provided by this example; other materials and preparation method are the same as in Example 1.

A PCB is provided, which differs from Example 1 only in that a resin adhesive film is the resin adhesive film provided by this example; other materials and preparation method are the same as in Example 1.

### Example 4

A resin composition includes the following components in parts by weight: 100 parts of an epoxy resin (ESN-375 of Nippon Steel & Sumikin Chemical Co., Ltd and NC3000 of Nippon Kayaku Co., Ltd combined at a mass ratio of 50:50), 5 parts of a carbodiimide compound (Stabaxol P2400 of Rhein Chemie), 50 parts of a polyamide-imide resin (SP1A-2 of Guangdong Yinxi Technology Co., Ltd), 45 parts of a phenolic resin (SH-5085 of Shandong Shengquan Co., Ltd), 200 parts of silicon dioxide and 0.1 part of a curing accelerator (2-MI); the silicon dioxide includes 180 parts of micron-sized silicon dioxide (with an average particle size of 1.5 μm) and 20 parts of nano-sized silicon dioxide (with an average particle size of 50 nm).

A resin adhesive film is provided, which differs from Example 1 only in that a material of the resin layer is the resin composition provided by this example; other materials and preparation method are the same as in Example 1.

A PCB is provided, which differs from Example 1 only in that a resin adhesive film is the resin adhesive film provided by this example; other materials and preparation method are the same as in Example 1.

### Example 5

A resin composition is provided, which differs from Example 3 only in that an amount of the carbodiimide compound is 10 parts; other components and amounts are the same as in Example 3.

A resin adhesive film is provided, which differs from Example 1 only in that a material of the resin layer is the resin composition provided by this example; other materials and preparation method are the same as in Example 1.

A PCB is provided, which differs from Example 1 only in that a resin adhesive film is the resin adhesive film provided by this example; other materials and preparation method are the same as in Example 1.

### Example 6

A resin composition is provided, which differs from Example 3 only in that an amount of the carbodiimide compound is 15 parts; other components and amounts are the same as in Example 3.

A resin adhesive film is provided, which differs from Example 1 only in that a material of the resin layer is the resin composition provided by this example; other materials and preparation method are the same as in Example 1.

A PCB is provided, which differs from Example 1 only in that a resin adhesive film is the resin adhesive film provided by this example; other materials and preparation method are the same as in Example 1.

### Example 7

A resin composition is provided, which differs from Example 1 only in that an amount of the polyethersulfone is 30 parts; other components and amounts are the same as in Example 1.

A resin adhesive film is provided, which differs from Example 1 only in that a material of the resin layer is the resin composition provided by this example; other materials and preparation method are the same as in Example 1.

A PCB is provided, which differs from Example 1 only in that a resin adhesive film is the resin adhesive film provided by this example; other materials and preparation method are the same as in Example 1.

### Example 8

A resin composition is provided, which differs from Example 2 only in that an amount of the polyethersulfone is 220 parts; other components and amounts are the same as in Example 2.

A resin adhesive film is provided, which differs from Example 1 only in that a material of the resin layer is the resin composition provided by this example; other materials and preparation method are the same as in Example 1.

A PCB is provided, which differs from Example 1 only in that a resin adhesive film is the resin adhesive film provided by this example; other materials and preparation method are the same as in Example 1.

### Example 9

A resin composition is provided, which differs from Example 1 only in that the silicon dioxide is micron-sized silicon dioxide solely (with an average particle size of 1 μm); other components and amounts are the same as in Example 1.

A resin adhesive film is provided, which differs from Example 1 only in that a material of the resin layer is the resin composition provided by this example; other materials and preparation method are the same as in Example 1.

A PCB is provided, which differs from Example 1 only in that a resin adhesive film is the resin adhesive film provided by this example; other materials and preparation method are the same as in Example 1.

### Example 10

A resin composition is provided, which differs from Example 3 only in that the silicon dioxide includes 170 parts of micron-sized silicon dioxide (with an average particle size of 1.5 μm) and parts of nano-sized silicon dioxide (with an average particle size of 50 nm); other components and amounts are the same as in Example 3.

A resin adhesive film is provided, which differs from Example 1 only in that a material of the resin layer is the resin composition provided by this example; other materials and preparation method are the same as in Example 1.

A PCB is provided, which differs from Example 1 only in that a resin adhesive film is the resin adhesive film provided by this example; other materials and preparation method are the same as in Example 1.

### Comparative Example 1

A resin composition includes the following components in parts by weight: 100 parts of an epoxy resin (ESN-375 of Nippon Steel & Sumikin Chemical Co., Ltd and NC3000 of Nippon Kayaku Co., Ltd combined at a mass ratio of 50:50), 5 parts of a carbodiimide compound (CARBODIIMIDE V-02B of Nisshinbo Chemical Inc), 100 parts of a phenoxy resin (53-BH-35 of Hexion), 45 parts of a phenolic resin (SN375 of Nippon Steel Chemical), 200 parts of silicon dioxide and 0.1 part of a curing accelerator (2-MI); the silicon dioxide includes 190 parts of micron-sized silicon dioxide (with an average particle size of 1 μm) and 10 parts of nano-sized silicon dioxide (with an average particle size of 50 nm).

A resin adhesive film is provided, which differs from Example 1 only in that a material of the resin layer is the resin composition provided by this comparative example; other materials and preparation method are the same as in Example 1.

A PCB is provided, which differs from Example 1 only in that a resin adhesive film is the resin adhesive film provided by this comparative example; other materials and preparation method are the same as in Example 1.

### Comparative Example 2

A resin composition includes the following components in parts by weight: 100 parts of an epoxy resin (ESN-375 of Nippon Steel & Sumikin Chemical Co., Ltd and NC3000 of Nippon Kayaku Co., Ltd combined at a mass ratio of 50:50), 5 parts of a carbodiimide compound (CARBODIIMIDE V-02B of Nisshinbo Chemical Inc), 50 parts of polycarbonate (purchased from Hubei Jusheng Technology Co. Ltd), 45 parts of a phenolic resin (SN375 of Nippon Steel Chemical), 200 parts of silicon dioxide and 0.1 part of a curing accelerator (2-MI); the silicon dioxide includes 190 parts of micron-sized silicon dioxide (with an average particle size of 1 μm) and 10 parts of nano-sized silicon dioxide (with an average particle size of 50 nm).

A resin adhesive film is provided, which differs from Example 1 only in that a material of the resin layer is the resin composition provided by this comparative example; other materials and preparation method are the same as in Example 1.

A PCB is provided, which differs from Example 1 only in that a resin adhesive film is the resin adhesive film provided by this comparative example; other materials and preparation method are the same as in Example 1.

### Comparative Example 3

A resin composition includes the following components in parts by weight: 100 parts of an epoxy resin (ZX1059 of Nippon Steel & Sumikin Chemical Co., Ltd, HP-4710 of DIC, and NC3000 of Nippon Kayaku Co., Ltd combined at a mass ratio of 10:40:50), 5 parts of a carbodiimide compound (CARBODIIMIDE V-07 of Nisshinbo Chemical Inc), 45 parts of a phenolic resin (SN375 of Nippon Steel Chemical), 200 parts of silicon dioxide and 0.1 part of a curing accelerator (2-methylimidazole, 2-MI); the silicon dioxide includes 198 parts of micron-sized silicon dioxide (with an average particle size of 1 μm) and 2 parts of nano-sized silicon dioxide (with an average particle size of 50 nm).

A resin adhesive film is provided, which differs from Example 1 only in that a material of the resin layer is the resin composition provided by this comparative example; other materials and preparation method are the same as in Example 1.

A PCB is provided, which differs from Example 1 only in that a resin adhesive film is the resin adhesive film provided by this comparative example; other materials and preparation method are the same as in Example 1.

### Comparative Example 4

A resin composition includes the following components in parts by weight: 100 parts of an epoxy resin, 50 parts of polyethersulfone, 50 parts of a phenolic resin, 200 parts of silicon dioxide and 0.1 part of a curing accelerator (2-MI); the silicon dioxide includes 198 parts of micron-sized silicon dioxide (with an average particle size of 1 μm) and 2 parts of nano-sized silicon dioxide (with an average particle size of 50 nm); the specific types of each component are the same as in Example 1.

A resin adhesive film is provided, which differs from Example 1 only in that a material of the resin layer is the resin composition provided by this comparative example; other materials and preparation method are the same as in Example 1.

A PCB is provided, which differs from Example 1 only in that a resin adhesive film is the resin adhesive film provided by this comparative example; other materials and preparation method are the same as in Example 1.

The resin adhesive films and PCBs provided by Examples 1-10 and Comparative Examples 1-4 are subjected to performance tests, and the specific testing methods are as follows:
(1) film-forming performance and powder-falling performance of resin adhesive film: the resin adhesive film is wound and packaged in a circular tube with a diameter of 100 mm and observed for cracks, powder falling, and the like;
(2) moisture and heat resistance stability (PCT) of PCB: the test is performed with immersion tin at 288° C., in accordance with the method specified in IPC-TM-650;
(3) reflow soldering on PCB: the reflow soldering test is performed in accordance with the method specified in IPC-TM-650;
(4) peel strength (PS) of PCB: the test is performed in accordance with the method specified in IPC-TM-650;
(5) modulus: the modulus of the resin adhesive film is tested by the dynamic thermo-mechanical analysis (DMA) in accordance with the method specified in IPC-TM-650; and
(6) glass transition temperature (Tg): the Tg of the resin adhesive film is tested by the DMA method in accordance with the method specified in IPC-TM-6500.

The specific test results are shown in Table 1.

TABLE 1

| | | PCT | | | | |
|---|---|---|---|---|---|---|
| | | (with im- | | | | |
| | | mersion | | | | |
| | Powder | tin at | Reflow | PS | Modulus | Tg |
| | falling | 288° C.) | soldering | (N/mm) | (GPa) | (° C.) |
| Example 1 | No powder | >30 min | >10 times | 0.80 | 6.3 | 175 |
| | falling | | | | | |
| Example 2 | No powder | >30 min | >10 times | 0.85 | 6.5 | 174 |
| | falling | | | | | |
| Example 3 | No powder | >30 min | >10 times | 0.85 | 6.6 | 175 |
| | falling | | | | | |
| Example 4 | No powder | >30 min | >10 times | 0.80 | 6.0 | 173 |
| | falling | | | | | |
| Example 5 | No powder | >30 min | >10 times | 0.85 | 6.5 | 173 |
| | falling | | | | | |
| Example 6 | No powder | 28 min | 8 times | 0.95 | 6.4 | 175 |
| | falling | | | | | |
| Example 7 | No powder | 29 min | 9 times | 0.80 | 6.0 | 170 |
| | falling | | | | | |
| Example 8 | No powder | 27 min | 8 times | 0.80 | 6.8 | 180 |
| | falling | | | | | |
| Example 9 | No powder | >30 min | >10 times | 0.81 | 5.7 | 176 |
| | falling | | | | | |
| Example 10 | No powder | 29 min | 9 times | 0.70 | 6.0 | 170 |
| | falling | | | | | |
| Com- | No powder | <10 min | <3 times | 0.80 | 4.5 | 150 |
| parative | falling | | | | | |
| Example 1 | | | | | | |
| Com- | No powder | <10 min | <3 times | 0.70 | 4.3 | 152 |
| parative | falling | | | | | |
| Example 2 | | | | | | |
| Com- | Easy to | >30 min | >10 times | 0.45 | 5.3 | 155 |
| parative | shed | | | | | |
| Example 3 | powders | | | | | |
| | and crack | | | | | |
| Com- | No powder | >30 min | >10 times | 0.4 | 6.4 | 172 |
| parative | falling | | | | | |
| Example 4 | | | | | | |

As can be seen from the performance test data in Table 1, the resin compositions and the resin adhesive films and the PCBs containing the same provided by Examples 1-5 of the present application have excellent overall performance; the resin adhesive film has good film-forming performance and dose not shed powders or crack; the moisture and heat resistance stability test of the PCB (with immersion tin at 288° C.) is performed for more than 30 min, the reflow soldering is performed for more than 10 times, the peel strength is 0.80-0.85 N/mm, the modulus is 6.0-6.6 GPa, and the glass transition temperature Tg is more than or equal to 173° C.; the heat resistance and reliability are good, and the peeling strength is high, which fully satisfies the performance requirements of printed circuit boards and chip packaging.

Furthermore, with the resin composition provided by the present application prepared by combining the epoxy resin, carbodiimide compound, phenolic resin, modified polymer (polyethersulfone or a polyamide-imide resin) and silicon dioxide in a specific ratio, the resin adhesive film and PCB containing the resin composition are enabled to have excellent film-forming performance, heat resistance, toughness and adhesive force. In a case where the carbodiimide compound and the epoxy resin have a mass ratio of 0.01-0.1:1 and a mass of the modified polymer is 30-100% of a total mass of the epoxy resin, the carbodiimide compound and the phenolic resin, the resin composition, the resin adhesive film and the PCB can realize the optimized performances; if the content of the carbodiimide compound is relatively high (Example 6), the heat resistance of the resin will be affect, resulting in deterioration of PCT (with immersion tin at 288° C.) and reflow soldering performances; if the amount of the modified polymer is relatively high (Example 8), the resin will have poor dispersibility during the adhesive preparation, resulting in deterioration of PCT (with immersion tin at 288° C.) and reflow soldering performances; if the amount of the modified polymer is relatively low (Example 7), the PCT (with immersion tin at 288° C.) and reflow soldering performances will be degraded. In addition, the silicon dioxide contains nano-sized silicon dioxide in a specific ratio, which is conducive to further improving the modulus and toughness of the resin adhesive film; if the silicon dioxide is in micron scale solely (Example 9), the modulus of the resin adhesive film will decrease, and the strength and toughness will be weakened; if the content of the nano-sized silicon dioxide is too high (Example 10), the nano-particles will easily agglomerate together, thereby affecting the heat resistance, and degrading the PCT (with immersion tin at 288° C.) and reflow soldering performances.

In the present application, the modified polymer (polyethersulfone or a polyamide-imide resin), carbodiimide compound and phenolic resin perform a synergistic effect and react with the epoxy resin together, which gives the resin composition excellent heat resistance, film-forming performance, toughness, and adhesive performance; if the specific modified polymer is replaced with a plasticizing resin (Comparative Examples 1 and 2), the resin composition will have a low glass transition temperature, and the heat resistance, the moisture and heat resistance stability, the reliability, and the adhesive force will all be reduced significantly; if the system does not contain the plasticizing component (Comparative Example 3), the resin adhesive film will shed powders and crack and have poor film-forming performance, low peel strength, and deteriorated adhesive performance, which cannot meet the use requirements. If the resin composition does not contain the carbodiimide compound (Comparative Example 4), the peel strength will be low, and the adhesive force will be significantly reduced, which cannot meet the use requirements.

The applicant has stated that although a resin composition, a resin adhesive film and an application thereof provided by the present application are described through the embodiments in the present application, the present application is not limited to the embodiments, which means that the present application does not necessarily rely on the embodiments to be implemented. It is to be understood by those skilled in the art that any modifications to the present application, equivalent substitutions of the various raw materials and additions of auxiliary components for the products of the present application, selection of specific methods, etc., all fall within the protection scope and disclosure scope of the present application.

1-10. (canceled)

11. A resin composition, which comprises the following components in parts by weight: 80-120 parts of an epoxy resin, 1-10 parts of a carbodiimide compound, 30-130 parts of a phenolic resin, 20-250 parts of a modified polymer and 50-500 parts of silicon dioxide; the modified polymer is selected from polyethersulfone or a polyamide-imide resin.

12. The resin composition according to claim 11, wherein the epoxy resin comprises any one or a combination of at least two of a bisphenol A epoxy resin, a bisphenol F epoxy resin, a biphenyl epoxy resin, an epoxy resin having a naphthalene structure, a dicyclopentadiene epoxy resin or a PPO modified epoxy resin.

13. The resin composition according to claim 11, wherein the phenolic resin comprises any one or a combination of at least two of a biphenyl phenolic resin, an o-cresol phenolic resin, a phenolic resin having a naphthalene structure or a dicyclopentadiene phenolic resin.

14. The resin composition according to claim 11, wherein the polyethersulfone has a weight average molecular mass of 5000-50000.

15. The resin composition according to claim 11, wherein the polyamide-imide resin has a weight average molecular mass of 5000-50000.

16. The resin composition according to claim 11, wherein the silicon dioxide has a mass percentage of 40-80% in the resin composition.

17. The resin composition according to claim 11, wherein the resin composition further comprises 0.01-5 parts of a curing accelerator by weight.

18. A resin varnish, which comprises a solvent, and the resin composition according to claim 1 dissolved or dispersed in the solvent.

19. A resin adhesive film, wherein a material of the resin adhesive film comprises the resin composition according to claim 11.

20. The resin composition according to claim 11, wherein the carbodiimide compound and the epoxy resin have a mass ratio of (0.01-0.1):1.

21. The resin composition according to claim 11, wherein based on a total mass of the epoxy resin, the carbodiimide compound and the phenolic resin being 100%, a mass of the modified polymer is 30-100%.

22. The resin composition according to claim 11, wherein the silicon dioxide is spherical silicon dioxide.

23. The resin composition according to claim 22, wherein the spherical silicon dioxide has a particle size of less than or equal to 2 μm.

24. The resin composition according to claim 22, wherein the spherical silicon dioxide comprises nano-sized silicon dioxide, and the nano-sized silicon dioxide has a particle size of 10-100 nm;

25. The resin composition according to claim 24, wherein based on a total mass of the organic compounds in the resin composition being 100%, the nano-sized silicon dioxide has a mass of 1-10%.

26. The resin composition according to claim 11, wherein the silicon dioxide is silicon dioxide with surface treatment.

27. A method for preparing a printed circuit board or chip packaging, comprising using the resin adhesive film according to claim 19.
